(19) United States
(12) Patent Application Publication
(10) Pub. No.: US 2017/0088773 A1
(43) Pub. Date: Mar. 30, 2017

(54) MATERIAL OF PHOSPHOR AND A MANUFACTURING METHOD THEREOF

(71) Applicant: EPISTAR CORPORATION, Hsinchu (TW)

(72) Inventors: Shin-Ying Lin, Hsinchu (TW); Chun-Che Lin, Hsinchu (TW); Ru-Shi Liu, Hsinchu (TW); Ming-Chi Hsu, Hsinchu (TW); Ai-Sen Liu, Hsinchu (TW)

(21) Appl. No.: 15/273,053

(22) Filed: Sep. 22, 2016

(30) Foreign Application Priority Data
Sep. 24, 2015 (TW) 104131527

(51) Int. Cl. C09K 11/77; H01L 33/56; H01L 33/50

(52) U.S. Cl. CPC C09K 11/7734; H01L 33/502; H01L 33/507; H01L 33/56

(57) ABSTRACT

An embodiment of the present disclosure discloses a phosphor material and a manufacturing method thereof. The general composition of the phosphor material is A₂₋ₓMO₄:Euₓ, wherein A includes a single element or at least two elements selected from the group consisting of Ca, Sr, and Ba, M is Si, Ge or combination thereof, wherein x is greater than 0.01 and 2-x>0. The phosphor material can be excited by a first excitation wavelength and emit a first emission spectrum and, excited by a second excitation wavelength and emit a second emission spectrum. The first excitation wavelength is different from the second excitation wavelength, and the first emission spectrum is different from the second emission spectrum.

### CROSS REFERENCE TO RELATED APPLICATION

This application claims the priority to and the benefit of TW application Ser. No. 104131527 filed on Sep. 24, 2015, and the content of which is hereby incorporated by reference in its entirety.

### BACKGROUND OF THE DISCLOSURE

Technical Field

This present application relates to a phosphor material and the manufacturing method thereof, and in particular to the phosphor material represented by the general formulas:
A₂₋ₓMO₄:Euₓ, wherein A is one or at least two elements selected from the group consisting of Ca, Sr, and Ba, M is Si, Ge or combination thereof, and x is greater than 0.01 and 2-x>0.

Description of the Related Art

The manufacturing method of White Light-Emitting Diodes (WLEDs) has several approaches. The first approach is using blue LED to excite the yellow phosphor. The second approach is using blue LED to excite green phosphor and red phosphor. The third approach is combining red LED, green LED and blue LED to respectively emit one color light and then mixing them to generate white light. The fourth approach is using UV LED to excite the phosphor.

White Light-Emitting Diodes have longer life span, better energy efficiency, smaller volume, faster response time, better shock resistance compared with traditional incandescent light bulbs. Therefore, white light-emitting diodes have been adopted gradually in various lighting devices. Although auxiliary lighting, including flash lights, car interior lights, architectural decorative lighting products, is still the main market of white light-emitting diodes in the lighting market, white light-emitting diodes are expected to replace traditional lighting products in the future and become the mainstream of the lighting products in global market.

For white light-emitting diodes, phosphor is an important factor affecting luminous efficiency of white light-emitting diodes. The color render index of the white light generated from a yellow phosphor excited by a blue LED is not good. After many years of research and development, it is found that using a high efficient UV-light-emitting diode (UV-LED) as an excitation light source is another way of white light-emitting diodes. Because the UV-LED technique becomes mature, the phosphor development for the UV-LED is more and more important.

### SUMMARY OF THE DISCLOSURE

The embodiment of the present disclosure discloses a phosphor material represented by the general formula:
A₂₋ₓMO₄:Euₓ, wherein A is one or at least two elements selected from the group consisting of Ca, Sr, and Ba, M is Si, Ge or combination thereof, and x is greater than 0.01 and 2-x>0. The phosphor material is excited to generate a first emission spectrum by a first excitation wavelength, and is excited to generate a second emission spectrum by a second excitation wavelength. Moreover, the first excitation wavelength is different from the second excitation wavelength, and the first emission spectrum is different from the second emission spectrum.

The other embodiment of the present disclosure discloses a phosphor material of a silicate compound. The phosphor material can be excited to a first emission spectrum by a first excitation wavelength, and be excited to a second emission spectrum by a second wavelength. Furthermore, a difference between a peak wavelength in the first emission spectrum and a peak wavelength in the second emission spectrum is greater than 50 nm.

The other embodiment of the present disclosure discloses a manufacturing method of a phosphor material. The phosphor material represented by the general formulas:
A₂₋ₓMO₄:Euₓ, wherein A is one or at least two elements selected from the group consisting of Ca, Sr, and Ba, M is Si, Ge or combination thereof, and x is greater than 0.01 and 2-x>0. The manufacturing method includes a first sintering step and a second sintering step. Moreover, a temperature of the second sintering step is higher than a temperature of the first sintering step, and the second sintering step includes introducing a gas of a reduced atmosphere.

### BRIEF DESCRIPTION OF THE DRAWINGS

FIG. 1 shows X-ray powder diffraction pattern in the preparation of the phosphor material disclosed in the embodiment of the present disclosure.

FIG. 2 shows X-ray powder diffraction pattern in the preparation of the phosphor material disclosed in another embodiment of the present disclosure.

FIG. 3 shows an excitation spectrum under the wavelength band of ultraviolet light and an emission spectrum in the preparation of the phosphor material disclosed in the embodiment of the present disclosure.

FIG. 4 shows an excitation spectrum under the wavelength band of blue light and an emission spectrum in the preparation of the phosphor material disclosed in the embodiment of the present disclosure.

FIGS. 5a and 5b show the mechanism of fluorescent emission of the phosphor material in the embodiment of the present disclosure.

### DETAILED DESCRIPTION OF THE PREFERRED EMBODIMENTS

Exemplary embodiments of the present application will be described in detail with reference to the accompanying drawings hereafter. The following embodiments are given by way of illustration to help those skilled in the art fully understand the spirit of the present application. Hence, it should be noted that the present disclosure is not limited to the embodiments herein and can be realized by various forms. Further, the drawings are not precise scale and components may be exaggerated in view of width, height, length, etc. Herein, the similar or identical reference numerals will denote the similar or identical components throughout the drawings.

In the embodiment of the present disclosure, a phosphor material is disclosed represented by the general formula:
A₂₋ₓMO₄:Euₓ, wherein A is one or at least two elements selected from the group consisting of Ca, Sr, and Ba, M is Si, Ge or combination thereof, and x is greater than 0.01 and 2-x>0. In one embodiment, the phosphor material is a silicate compound, represented by the general formula: Ca₂₋ₓSiO₄:Euₓ²⁺, and x=0.1-0.6.

In one embodiment of the present disclosure, the phosphor material can be excited to generate a first emission spectrum Eₘ₁ by a first excitation wavelength Eₓ₁, and be excited to generate a second emission spectrum Eₘ₂ by a second excitation wavelength Eₓ₂. Furthermore, the first excitation wavelength Eₓ₁ is different from the second excitation wavelength Eₓ₂, and the first emission spectrum Eₘ₁ is different from the second emission spectrum Eₘ₂. In one embodiment, the difference between a peak wavelength in the first emission spectrum and the peak wavelength in the second emission spectrum is greater than 50 nm. In another embodiment, the difference between a peak wavelength in the first emission spectrum and the peak wavelength in the second emission spectrum is between 60 nm and 160 nm.

In one embodiment, the light source is an ultraviolet light-emitting element, such as a ultraviolet light-emitting diode. The ultraviolet light-emitting element emits ultraviolet light as the first excitation wavelength Eₓ₁. In another embodiment, the light source is an ultraviolet laser. In one embodiment, a peak wavelength of the first excitation wavelength is ranging from 300 nm to 400 nm. In another embodiment, a peak wavelength of the first excitation wavelength is ranging from 320 nm to 380 nm. In one embodiment, the first emission spectrum Eₘ₁ emits green light, and a peak wavelength of the first emission spectrum Eₘ₁ is ranging from 500 nm to 560 nm. In another embodiment, a peak wavelength of the first emission spectrum Eₘ₁ is ranging from 510 nm to 540 nm. In one embodiment, the light source is a blue light-emitting element, such as a blue light-emitting diode. The blue light-emitting diode emits blue light as the second excitation wavelength Eₓ₂. In another embodiment, the second excitation wavelength Eₓ₂ is emitted from a phosphor capable of emitting blue light when being excited by the ultraviolet light-emitting element, wherein the phosphor can be BaMgAl₁₀O₁₇:Eu²⁺ (BAM) or (Ba, Sr, Ca)₃MgSi₂O₈:Eu²⁺. In one embodiment, a peak wavelength of the second excitation wavelength is ranging from 420 nm to 480 nm or ranging from 440 nm to 470 nm. In one embodiment, a peak wavelength of the first emission spectrum Eₘ₂ is ranging from 600 nm to 660 nm or ranging from 600 nm to 630 nm.

A manufacturing method is described in detail below. In one embodiment, Ca₂₋ₓSiO₄:Euₓ²⁺, x=0.1-0.6, is prepared by solid-state sintering reaction (solid-state reaction). First, a specific amount of each of CaCO₃, SiO₂ and Eu₂O₃ is put into a crucible and ground for twenty minutes. To form Ca_{1.9}SiO₄:Eu_{0.1}²⁺, a mole ratio of each of the three reactants CaCO₃, SiO₂ and Eu₂O₃ is 64.41%, 33.90% and 1.69% respectively, and a weight ratio is 71.00%, 22.42% and 6.58% respectively. To form Ca_{l.4}SiO₄:Eu_{0.6} ²⁺ , a mole ratio of each of the three reactants CaCO₃, SiO₂ and Eu₂O₃ is 51.85%, 37.04% and 11.11% respectively, and a weight ratio is 45.81%, 19.63% and 34.56% respectively. After grinding, two steps of sintering, including first sintering step and second sintering step, are performed. Moreover, a temperature of the second sintering step is higher than a temperature of the first sintering step. In one embodiment, a sintering condition of the first sintering step is to sinter the three reactants under air on 1050° C. for four hours, and the second sintering step is to carry out under a reduced atmosphere. The gas of the reduced atmosphere can be H₂. In another embodiment, the second sintering step is performed in a mixture of 5% H₂ and 95% N₂ under 1350° C. for four hours. A product Ca₂₋ₓSiO₄:Euₓ²⁺ can be obtained by two steps of sintering. The method can be easy to operate for mass production and the cost of material is low.

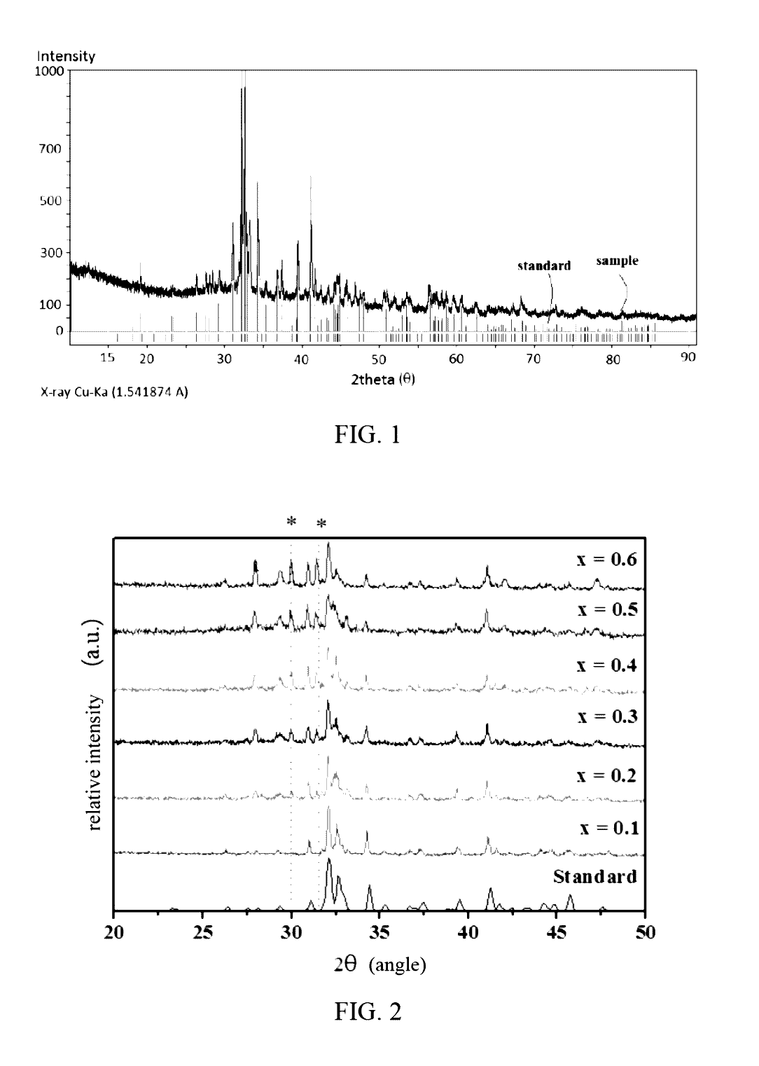

FIG. 1 shows X-ray powder diffraction pattern from preparing the phosphor material in accordance with one or more embodiments. X-ray powder diffraction instrument (Bruker company, model No.D2 phaser) is used to identify the crystalline phase. In detail, the sample prepared by the solid-state reaction disclosed in the embodiments is compared with a standard Ca₂SiO₄ compound (standard, JCPDS: 83-0460) in the X-ray powder diffraction patterns. In accordance with the X-ray powder diffraction patterns, Ca_{1.9}SiO₄:Eu_{0.1}²⁺ prepared by the solid-state reaction has the same crystalline phase as the standard Ca₂SiO₄ compound, and Eu mainly replaces the lattice position of Ca as an activity center.

FIG. 2 shows X-ray powder diffraction patterns from the phosphor material of Ca₂₋ₓSiO₄:Euₓ²⁺ (x=0.1-0.6) in accordance with several embodiments of present disclosure. In FIG. 2, samples from the bottom to the top of the drawing are the standard Ca₂SiO₄ compound with x=0.1, x=0.2, x=0.3, x=0.4, x=0.5 and x=0.6 in order. When the patterns of the samples with different Eu content in present disclosure are compared, the crystal structure is less likely affected by Eu content. Furthermore, the crystalline phases of the samples in the embodiment are the same as the standard Ca₂SiO₄ compound.

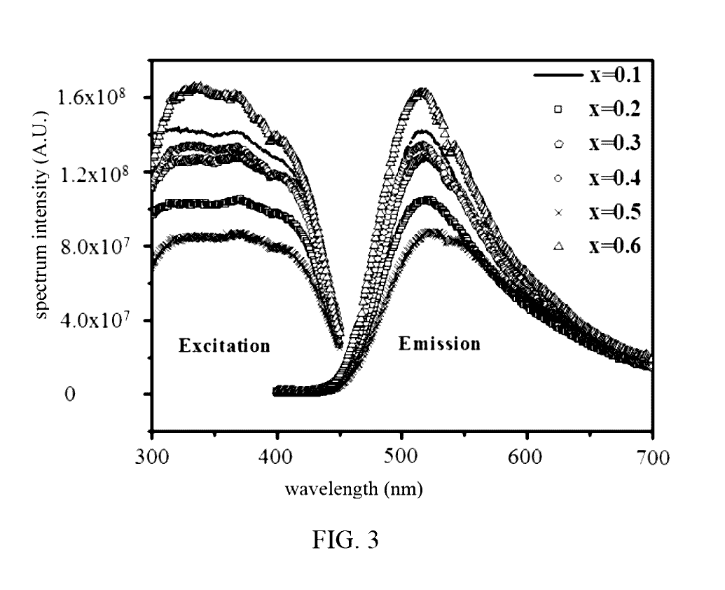

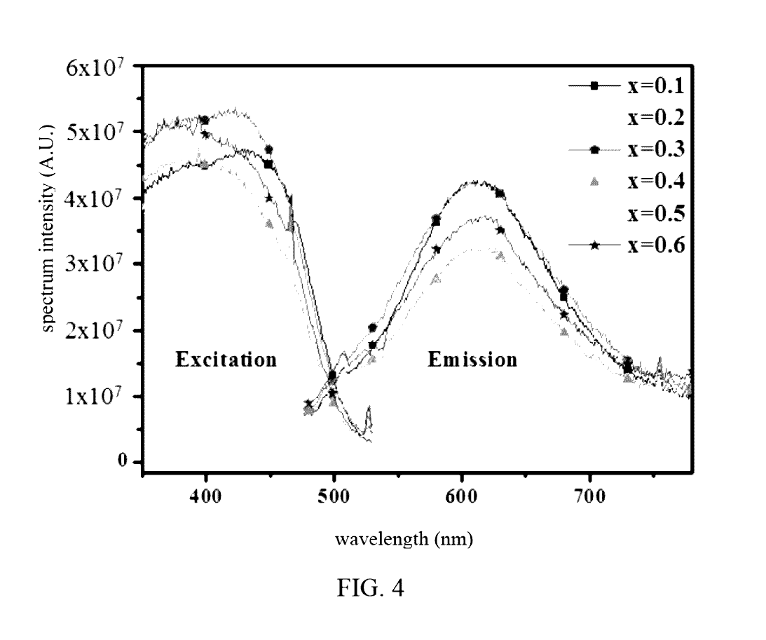

FIG. 3 and FIG. 4 show an excitation and an emission spectrum of the phosphor material of Ca₂₋ₓSiO₄:Euₓ²⁺ (x =0.1-0.6) in accordance with one embodiment of present disclosure. The excitation and emission spectrums are measured by a spectrophotometer (Horiba company, model No. FluoroMax-3). Moreover, the x-axis in the spectrum (FIG. 3 and FIG. 4) expresses the wavelength and the unit is nm. The y-axis expresses intensity and the unit is Arbitrary Unit, A.U. The left side in the spectrum in FIG. 3 and FIG. 4) is the excitation spectrum and the right side is the emission spectrum.

Referring to FIG. 3, Ca₂₋ₓSiO₄:Euₓ²⁺ (x =0.1-0.6) compound can be excited by ultraviolet light ranging from 320 nm to 380 nm and emit green light with maximum emission wavelength (peak wavelength) ranging from 510 nm to 520 nm. Though the compound has different Eu content, all wavelengths in the excitation and emission spectrum do not change obviously and the intensities have a little variation.

Referring to FIG. 4, Ca₂₋ₓSiO₄:Euₓ²⁺ (x =0.1-0.6) compound can be excited by blue light ranging from 430 nm to 470 nm and emit red light of maximum emission wavelength (peak wavelength) ranging from 610 nm to 630 nm. Similar in the result, though the compound has different Eu content, all wavelengths in the excitation and emission spectrum do not change obviously and the intensities have a little variation.

In FIG. 3 and FIG. 4, the phosphor material disclosed in the embodiment of present disclosure can be respectively excited by ultraviolet light and blue light to emit green light and red light, therefore, the green light and the red light are mixed with blue light so as to produce white light.

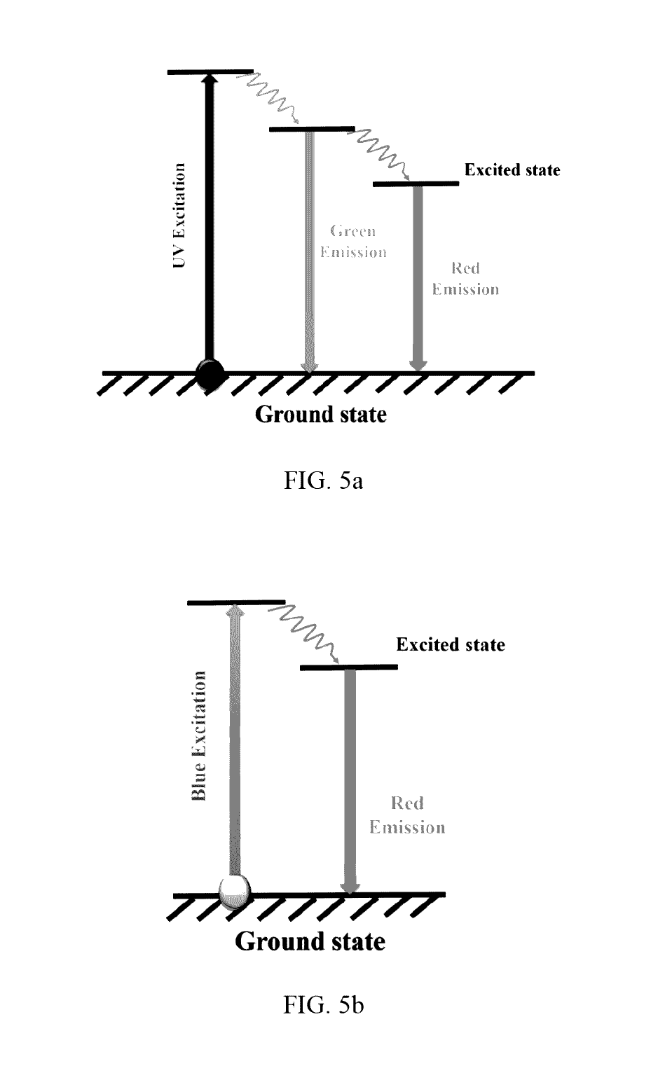

FIG. 5a and FIG. 5b show a mechanism of fluorescent emission of the phosphor material disclosed in the embodiment of the present disclosure. The Ca₂SiO₄:Eu²⁺ compound may have two different energy states at excited state and result in two different crystalline phases. Therefore, the electron can jump from the ground state to two different excited states when the electron absorbs different energy from different light sources of excitation respectively. After that, the electron emits different wavelength light after vibration relaxation. Referring to FIG. 5a, the electron can jump to higher energy state at excited state by the ultraviolet light source with a higher energy and emit green light ranging from 500 nm to 550 nm through relaxation. Referring to FIG. 5b, the electron can jump to lower energy state at excited state by the blue light source with lower energy and emit red light ranging from 600 nm to 640 nm through relaxation.

The phosphor material in the embodiments of present disclosure can be excited by two light sources with different energy simultaneously and emit different wavelength lights. The above mentioned feature has several advantages when the phosphor material is used in an LED. Comparing with LED encapsulated with two types of phosphor materials, when one type of the phosphor material is encapsulated in LED, the encapsulated LED can be assembled to emit green light, red light and/or white light with higher light emitting efficiency of white light. Moreover, the procedure of the encapsulated LED can reduce the manufacturing cost and simplify the manufacturing process. As a result, the phosphor material used in the LED can improve the efficiency and cost of the LED.

Although the drawings and the illustrations shown above are corresponding to the specific embodiments individually, the unit, the practicing method, the designing principle, and the technical theory can be referred, exchanged, incorporated, collocated, coordinated except they are conflicted, incompatible, or hard to be put into practice together. Although the present application has been explained above, it is not the limitation of the range, the sequence in practice, the material in practice, or the method in practice. Any modification or decoration for present application is not detached from the spirit and the range of such.

What is claimed is:

1. A phosphor material, comprising a general formula represented by
A₂₋ₓMO₄:Euₓ, wherein A is one or at least two elements selected from the group consisting of Ca, Sr and Ba, M is Si, Ge or combination thereof, and x is greater than 0.01 and 2-x>0, wherein the phosphor material is excited by a first excitation wavelength to emit a first emission spectrum and excited by a second excitation wavelength to emit a second emission spectrum,
wherein the first excitation wavelength is different from the second excitation wavelength and the first emission spectrum is different from the second emission spectrum.

2. The phosphor material according to claim 1, wherein x=0.1˜0.6.

3. The phosphor material according to claim 1, wherein A is Ca and M is Si.

4. The phosphor material according to claim 1, wherein the first excitation wavelength is ultraviolet light and the second excitation wavelength is blue light.

5. The phosphor material according to claim 1, wherein a difference between a peak wavelength in the first emission spectrum and a peak wavelength in the second emission spectrum is greater than 50 nm.

6. The phosphor material according to claim 1, wherein a difference between a peak wavelength in the first emission spectrum and a peak wavelength in the second emission spectrum is ranging from 60 nm to 160 nm.

7. The phosphor material according to claim 1, wherein a peak wavelength in the first emission spectrum is ranging from 500 nm to 560 nm.

8. The phosphor material according to claim 1, wherein a peak wavelength in the second emission spectrum is ranging from 600 nm to 660 nm.

9. A phosphor material of silicate compound is configured to be excited by a first excitation wavelength to emit a first emission spectrum and excited by a second excitation wavelength to emit a second emission spectrum, wherein a difference between a peak wavelength in the first emission spectrum and a peak wavelength in the second emission spectrum is greater than 50 nm.

10. A manufacturing method of a phosphor material, comprising:
a first sintering step; and
a second sintering step, wherein a temperature of the second sintering is higher than a temperature of the first sintering temperature and the second sintering step comprises introducing a gas of a reduced atmosphere.
